(19) United States
(12) Patent Application Publication
(10) Pub. No.: US 2014/0117411 A1
(43) Pub. Date: May 1, 2014

(54) MONOLITHIC INTEGRATED CIRCUIT

(71) Applicant: Mitsubishi Electric Corporation, Tokyo (JP)

(72) Inventor: Ko Kanaya, Tokyo (JP)

(21) Appl. No.: 13/906,576

(22) Filed: May 31, 2013

(30) Foreign Application Priority Data
Oct. 26, 2012 (JP) 2012-236846

(51) Int. Cl. H01L 27/06

(52) U.S. Cl. CPC H01L 27/0629
USPC 257/195

(57) ABSTRACT

A monolithic integrated circuit includes: a substrate having a diode region and a transistor region; a first semiconductor layer on the substrate in the diode region and in the transistor region; a second semiconductor layer on the first semiconductor layer in the diode region and in the transistor region; a third semiconductor layer on the second semiconductor layer in the transistor region, but not located in the diode region; a first electrode in the diode region and connected to the first semiconductor layer; a second electrode in the diode region and connected to the second semiconductor layer; and a source electrode, a gate electrode, and a drain electrode which are on the third semiconductor layer.

### BACKGROUND OF THE INVENTION

1. Field of the Invention

The present invention relates to a monolithic integrated circuit wherein a transistor and a diode are integrated on a single substrate.

2. Background Art

In recent years, considerable R&D effort has been expended on transistors made of nitride semiconductor material, and such transistors have been applied to high power amplifiers and low noise amplifiers, etc. Since low noise amplifiers formed of nitride semiconductor have a higher input power tolerance than low noise amplifiers of other material, a receiver circuit using a low noise amplifier of nitride semiconductor need not be provided with an isolator in the stage preceding the low noise amplifier. A mixer for down-conversion is connected to the stage following the low noise amplifier. In the case of direct conversion mixers, which are widely used, their noise factor is primarily dependent on the low-frequency noise of the devices used therein. Diodes are often used as devices in mixers. It is desired, however, that these diodes be vertical diodes, which do not have the problem of current flowing across the surface, and be formed by a homojunction in order to reduce low-frequency noise.

### SUMMARY OF THE INVENTION

In conventional monolithic integrated circuits, each diode is formed by shorting together the source and the drain of a transistor, and it is easy to integrate such diodes and lateral transistors together on a single substrate. In contrast, it is difficult to integrate vertical diodes, which have lower low-frequency noise than lateral diodes, and lateral transistors together on a single substrate.

Further, a device has been proposed in which a diode layer is provided on a transistor layer, with a separation layer interposed therebetween (see, e.g., Japanese Laid-Open Patent Publication No. 2005-26242). This device has the problem of increased manufacturing cost, since it is necessary to form a diode layer separately from a transistor layer, in addition to forming a separation layer.

In view of the above-described problems, an object of the present invention is to provide a monolithic integrated circuit which can integrate a lateral transistor and a vertical diode on a single substrate without additional manufacturing cost.

According to the present invention, a monolithic integrated circuit includes: a substrate having a diode region and a transistor region; a first semiconductor layer on the substrate in the diode region and the transistor region; a second semiconductor layer on the first semiconductor layer in the diode region and the transistor region; a third semiconductor layer on the second semiconductor layer in the transistor region, the third semiconductor layer being not located in the diode region; a first electrode in the diode region and connected to the first semiconductor layer; a second electrode in the diode region and connected to the second semiconductor layer; and a source electrode, a gate electrode, and a drain electrode which are on the third semiconductor layer.

The present invention makes it possible to integrate a lateral transistor and a vertical diode on a single substrate without additional manufacturing cost.

Other and further objects, features and advantages of the invention will appear more fully from the following description.

### BRIEF DESCRIPTION OF THE DRAWINGS

FIG. 1 is a cross-sectional view showing a monolithic integrated circuit in accordance with a first embodiment of the present invention.

FIG. 2 is a cross-sectional view showing a monolithic integrated circuit in accordance with a second embodiment of the present invention.

FIG. 3 is a cross-sectional view showing a monolithic integrated circuit in accordance with a third embodiment of the present invention.

FIG. 4 is a cross-sectional view showing a monolithic integrated circuit in accordance with a fourth embodiment of the present invention.

FIG. 5 is a cross-sectional view showing a monolithic integrated circuit in accordance with a fifth embodiment of the present invention.

FIG. 6 is a cross-sectional view showing a monolithic integrated circuit in accordance with a sixth embodiment of the present invention.

FIG. 7 is a cross-sectional view showing a monolithic integrated circuit in accordance with a seventh embodiment of the present invention.

FIG. 8 is a cross-sectional view showing a monolithic integrated circuit in accordance with an eighth embodiment of the present invention.

FIG. 9 is a diagram showing a receiver circuit with a mixer in accordance with a ninth embodiment of the present invention.

FIG. 10 is a diagram showing a voltage-controlled oscillator with a varactor in accordance with a tenth embodiment of the present invention.

FIG. 11 is a diagram showing an amplifier with varactors in accordance with an eleventh embodiment of the present invention.

FIG. 12 is a diagram showing an amplifier with a multiplier in accordance with a twelfth embodiment of the present invention.

FIG. 13 is a diagram showing an amplifier with a protection circuit in accordance with a thirteenth embodiment of the present invention.

FIG. 14 is a diagram showing a switch in accordance with a fourteenth embodiment of the present invention.

FIG. 15 is a diagram showing a phase shifter in accordance with a fifteenth embodiment of the present invention.

FIG. 16 is a diagram showing an amplifier with a linearizer in accordance with a sixteenth embodiment of the present invention.

FIG. 17 is a diagram showing an inverter in accordance with a seventeenth embodiment of the present invention.

### DETAILED DESCRIPTION OF THE PREFERRED EMBODIMENTS

A monolithic integrated circuit according to the embodiments of the present invention will be described with reference to the drawings. The same components will be denoted by the same symbols, and the repeated description thereof may be omitted.

### First Embodiment

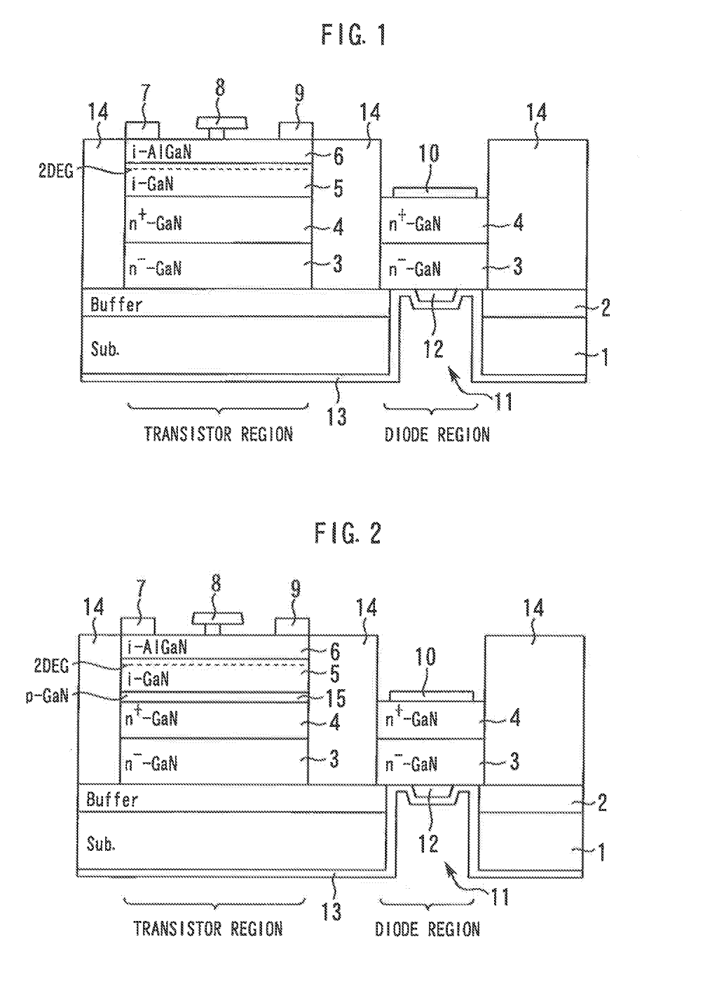

FIG. 1 is a cross-sectional view showing a monolithic integrated circuit in accordance with a first embodiment of the present invention. A substrate 1 has a diode region and a transistor region. In both the diode region and the transistor region, a buffer layer 2, an n⁻-type GaN Schottky layer 3, and an n³⁰ -type GaN ohmic layer 4 are sequentially provided on the substrate 1. The substrate 1 is made of material suitable for GaN-based epitaxial growth, such as Si, SiC, GaN, or sapphire.

In the transistor region, an i-type GaN electron traveling layer 5 is provided on the n⁺-type GaN ohmic layer 4, and an i-type AlGaN electron supply layer 6 is provided on the i-type GaN electron traveling layer 5. The GaN electron traveling layer 5 and the AlGaN electron supply layer 6 have been etched away from the diode region after forming these layers in both the transistor region and the diode region. It should be noted that although in this example the AlGaN electron traveling layer 5 is undoped, it may be of n-type.

A source electrode 7, a gate electrode 8, and a drain electrode 9 are provided on the AlGaN electron supply layer 6. In the diode region, a cathode electrode 10 is provided on the upper surface of the n⁺-type GaN ohmic layer 4. A via hole 11 is provided in the substrate 1 in the diode region. An anode electrode 12 is provided on the lower surface of the n⁻-type GaN Schottky layer 3 exposed in the via hole 11, and is connected to a bottom surface metal 13 on the bottom surface of the substrate 1.

An insulating layer 14 formed by insulation injection separates and insulates the n⁻-type GaN Schottky layer 3 and the n⁺-type GaN ohmic layer 4 in the diode region from the n⁻-type GaN Schottky layer 3 and the n⁺-type GaN ohmic layer 4 in the transistor region.

In accordance with the present embodiment, the n⁺-type GaN ohmic layer 4 and the n⁻-type GaN Schottky layer 3 are shared by the transistor and the diode. This eliminates the need to form diode layers separately from transistor layers. Thus the present embodiment makes it possible to integrate a lateral transistor and a vertical diode on a single substrate without additional manufacturing cost.

Since the AlGaN electron supply layer 6 has a wider bandgap than the GaN electron traveling layer 5, two-dimensional electron gas spreads in an area proximate the interface between the GaN electron traveling layer 5 and the AlGaN electron supply layer 6. As a result, the transistor functions as a high electron mobility transistor (HEMT) in which high mobility two-dimensional electron gas (2DEG) forms a channel.

Further, the n⁺-type GaN ohmic layer 4, the n⁻-type GaN Schottky layer 3, the anode electrode 12, and the cathode electrode 10 together form a Schottky barrier diode. Since the n⁺-type GaN ohmic layer 4 has a higher impurity concentration than the n⁻-type GaN Schottky layer 3, the diode has a reduced parasitic resistance. This reduction in the parasitic resistance results in a reduction in the low-frequency noise. Further, the n⁻-type GaN Schottky layer 3, which has a low impurity concentration, serves to reduce the junction capacitance of the Schottky junction, thereby increasing the cutoff frequency of the diode.

Further, since the bottom surface metal 13 is directly connected to the anode electrode 12 through the via hole 11, the inductive components between the anode electrode 12 and GND are reduced. This means that the use of this diode in a mixer will improve the high frequency characteristics of the mixer.

### Second Embodiment

FIG. 2 is a cross-sectional view showing a monolithic integrated circuit in accordance with a second embodiment of the present invention. In the transistor region of this monolithic integrated circuit, a p-type GaN layer 15 is provided between the n⁺-type GaN ohmic layer 4 and the GaN electron traveling layer 5. This p-type GaN layer 15 forms a barrier to reduce the current leaking from the two-dimensional electron gas to the substrate 1 side of the monolithic integrated circuit through the n⁺-type GaN ohmic layer 4.

### Third Embodiment

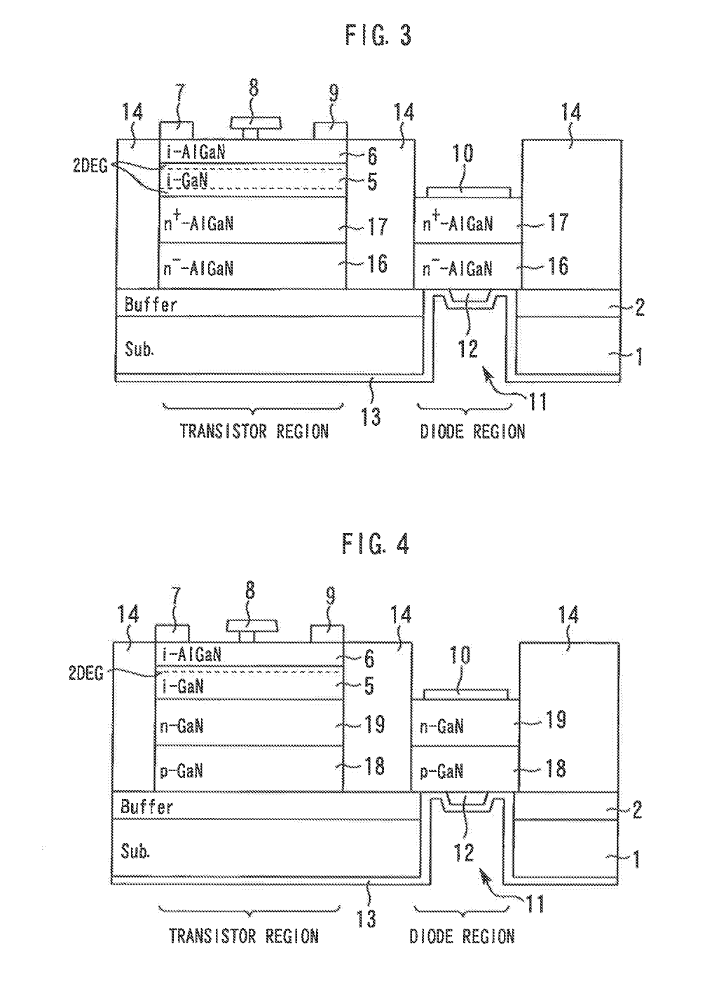

FIG. 3 is a cross-sectional view showing a monolithic integrated circuit in accordance with a third embodiment of the present invention. In the monolithic integrated circuit of the first embodiment, the two-dimensional electron gas may leak to the substrate 1 through the n⁺-type GaN ohmic layer 4. In order to prevent this, the monolithic integrated circuit of the third embodiment includes an n⁻-type AlGaN Schottky layer 16 and an n⁺-type AlGaN ohmic layer 17 instead of the n⁻-type GaN Schottky layer 3 and the n⁺-type GaN ohmic layer 4 of the first embodiment.

Since the n⁻-type AlGaN Schottky layer 16 and the n⁺-type AlGaN ohmic layer 17 have a wider bandgap than the GaN electron traveling layer 5, they act as barriers to prevent electrons from leaking from the two-dimensional electron gas to the substrate 1 side of the monolithic integrated circuit. Further, two-dimensional electron gas is also formed along the interface between the n⁺-type AlGaN ohmic layer 17 and the GaN electron traveling layer 5, thereby increasing the maximum drain current and the output power of the transistor.

### Fourth Embodiment

FIG. 4 is a cross-sectional view showing a monolithic integrated circuit in accordance with a fourth embodiment of the present invention. This monolithic integrated circuit includes, instead of the n⁻-type GaN Schottky layer 3 and the n⁺-type GaN ohmic layer 4 of the first embodiment, a p-type GaN layer 18 and an n-type GaN layer 19 sequentially stacked on the substrate 1. The anode electrode 12 is grounded through the bottom surface metal 13. This PN diode, whose anode is grounded, may be used as a varactor. In order to improve the linearity and the rate of change of capacitance of the varactor, it may be necessary to adjust the doping concentration and the thickness of the p-type GaN layer 18 and the n-type GaN layer 19. Further, if it is difficult to epitaxially grow the p-type GaN layer 18, then an i-type GaN layer may be used instead.

### Fifth Embodiment

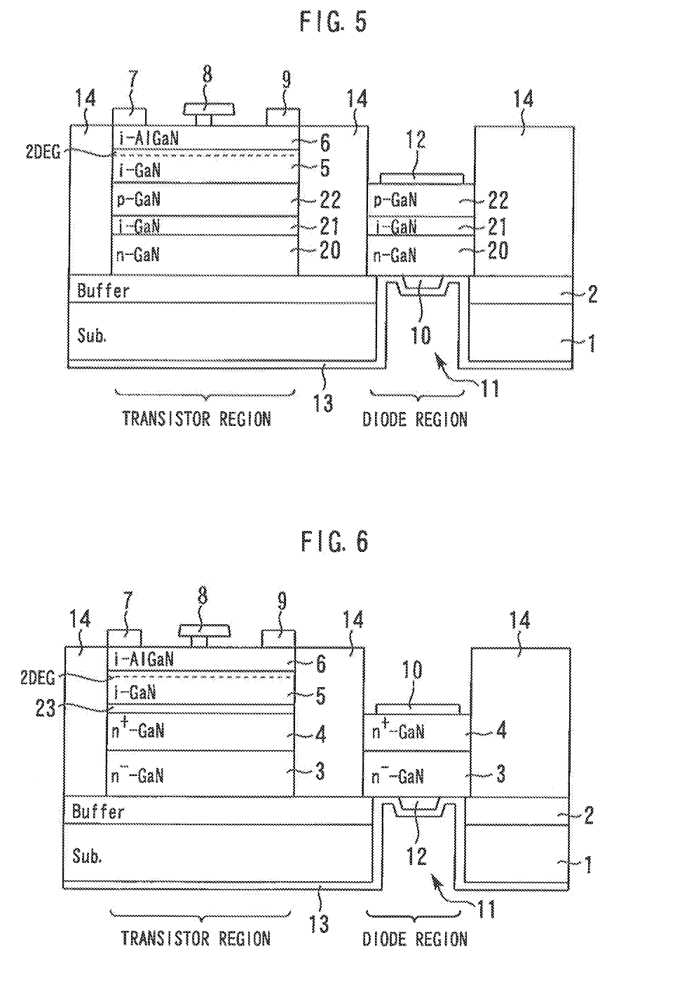

FIG. 5 is a cross-sectional view showing a monolithic integrated circuit in accordance with a fifth embodiment of the present invention. This monolithic integrated circuit includes, instead of the n⁻-type GaN Schottky layer 3 and the n⁺-type GaN ohmic layer 4 of the first embodiment, an n-type GaN layer 20, an i-type GaN layer 21, and a p-type GaN layer 22 sequentially stacked on the substrate 1. The p-type GaN layer 22 serves to reduce the current leaking from the two-dimensional electron gas to the substrate 1 side of the monolithic integrated circuit, as in the second embodiment. Further, since PIN diodes have a lower on resistance and a lower off capacitance than Schottky diodes, the PIN diode of this monolithic integrated circuit may be configured as a switch having low loss and high isolation characteristics.

### Sixth Embodiment

FIG. 6 is a cross-sectional view showing a monolithic integrated circuit in accordance with a sixth embodiment of the present invention. In this monolithic integrated circuit, an etch stopper layer 23 is provided between the n⁺-type GaN ohmic layer 4 and the GaN electron traveling layer 5. The material of the etch stopper layer 23 is AlGaN, AlN, etc. and its conductivity type is typically i-type. This etch stopper layer 23 is used as a stopper when the GaN electron traveling layer 5 and the AlGaN electron supply layer 6 in the diode region are etched.

### Seventh Embodiment

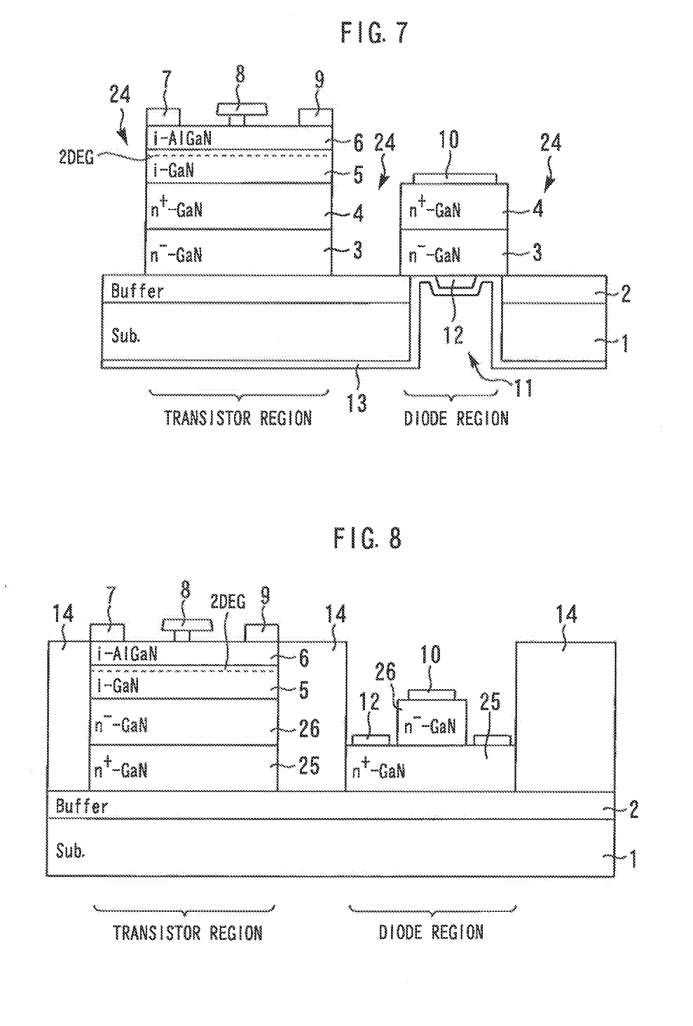

FIG. 7 is a cross-sectional view showing a monolithic integrated circuit in accordance with a seventh embodiment of the present invention. In this monolithic integrated circuit, the n⁻-type GaN Schottky layer 3 and the n⁺-type GaN ohmic layer 4 in the diode region are separated from the n⁻-type GaN Schottky layer 3 and the n⁺-type GaN ohmic layer 4 in the transistor region by a mesa 24. In this way, the diode region and the transistor region are separated and insulated from each other by the mesa 24 instead of the insulating layer 14 of the first embodiment, etc.

### Eighth Embodiment

FIG. 8 is a cross-sectional view showing a monolithic integrated circuit in accordance with an eighth embodiment of the present invention. The monolithic integrated circuit of the present embodiment does not have the via hole 11 described in connection with the first embodiment, etc. An n⁻-type GaN Schottky layer 26 is formed on an n⁺-type GaN ohmic layer 25. After forming the n⁺-GaN ohmic layer 25, the n⁻-type GaN Schottky layer 26, the GaN electron traveling layer 5, and the AlGaN electron supply layer 6 in both the transistor region and the diode region, the GaN electron traveling layer 5 and the AlGaN electron supply layer 6 in the diode region are etched away and a portion of the n⁻-type GaN Schottky layer 26 in the diode section is removed to expose a portion of the upper surface of the n⁺-type GaN ohmic layer 25.

In the diode region, cathode electrodes 10 are provided on the upper surface of the n⁺-type GaN ohmic layer 25 in an area where the n⁻-type GaN Schottky layer 26 has been removed. The anode electrode 12 is provided on the upper surface of the n⁻-type GaN Schottky layer 26.

Since the anode and the cathode can be wired on the substrate surface side of the monolithic integrated circuit, this diode can be used to form an antiparallel diode pair circuit, which is not connected to GND. This feature allows one to produce compact, low-cost mixers such as harmonic mixers. Other configurations and advantages of the present embodiment are the same as those of the first embodiment. Further, configurations of the present embodiment may be combined with those of the first to seventh embodiments.

### Ninth Embodiment

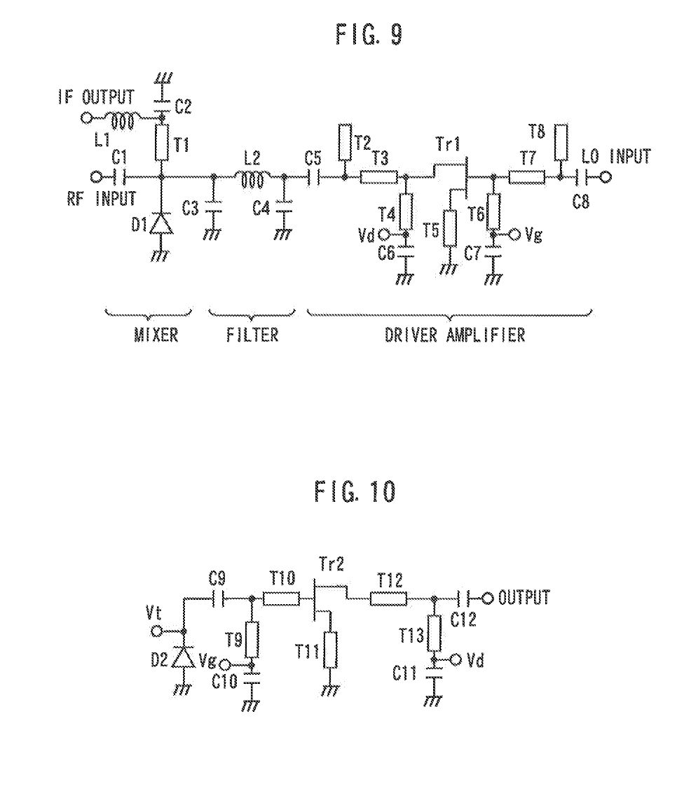

FIG. 9 is a diagram showing a receiver circuit with a mixer in accordance with a ninth embodiment of the present invention. Capacitances C1 and C2, a diode D1, an inductor L1, and a transmission line T1 together form a mixer. Capacitances C3 and C4 and an inductor L2 form a filter. Capacitances C5 to C8, transmission lines T2 to T8, and a transistor Tr1 form a driver amplifier.

In this receiver circuit, the diode D1 of the mixer may be configured as the vertical diode of any one of the first to eighth embodiments, and the transistor Tr1 of the amplifier may be configured as the lateral transistor of that embodiment. In this way, a vertical diode, in which current flows perpendicular to the substrate, is used in the mixer, so that the receiver circuit has low noise characteristics. Further, since this receiver circuit is configured in such a manner that a low noise amplifier having high power tolerance and a mixer having low noise characteristics are integrated together, the required mounting space of the receiver circuit can be reduced.

### Tenth Embodiment

FIG. 10 is a diagram showing a voltage-controlled oscillator with a varactor in accordance with a tenth embodiment of the present invention. This voltage-controlled oscillator has capacitances C9 to C12, a diode D2, transmission lines T9 to T13, and a transistor Tr2. The diode D2, which serves as a varactor, may be configured as the vertical diode of any one of the first to eighth embodiments, and the transistor Tr2 of the oscillator may be configured as the lateral transistor of that embodiment, thereby making it possible to form this voltage-controlled oscillator on a single chip.

### Eleventh Embodiment

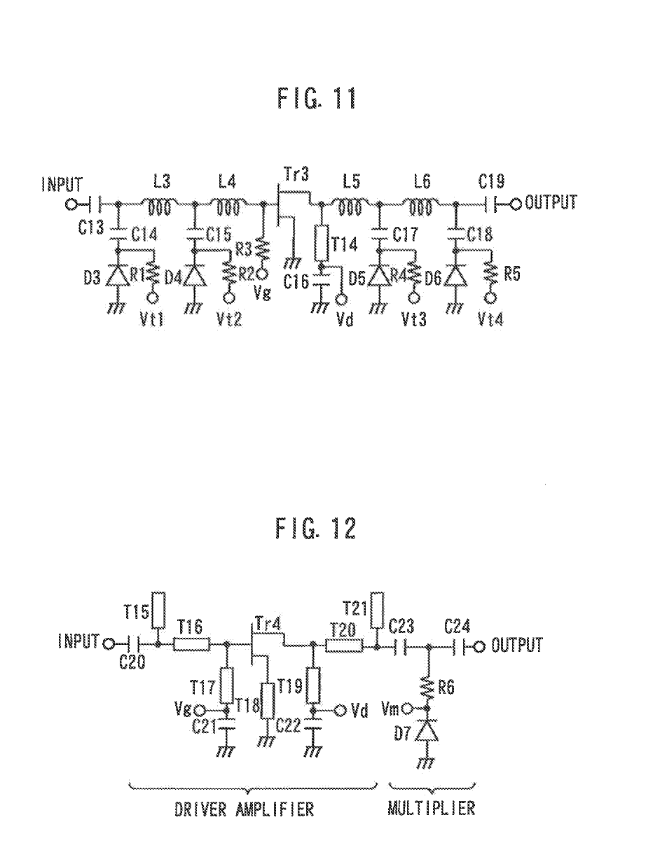

FIG. 11 is a diagram showing an amplifier with varactors in accordance with an eleventh embodiment of the present invention. This amplifier has capacitances C13 to C19, diodes D3 to D6, inductors L3 to L6, resistances R1 to R5, and a transistor Tr3. The diodes, or varactors, D3 to D6 of the matching circuits may be configured as the vertical diode of any one of the first to eighth embodiments, and the transistor Tr3 of the amplifier may be configured as the lateral transistor of that embodiment, thereby making it possible to reconfigure the amplifier by adjusting the matching frequencies.

### Twelfth Embodiment

FIG. 12 is a diagram showing an amplifier with a multiplier in accordance with a twelfth embodiment of the present invention. Capacitances C20 to C22, transmission lines T15 to T21, and a transistor Tr4 form a driver amplifier. Capacitances C23 and C24, a diode D7, and a resistance R6 form a multiplier. The diode 7 of the multiplier may be configured as the vertical diode of any one of the first to eighth embodiments, and transistor Tr4 of the amplifier may be configured as the lateral transistor of that embodiment, thereby making it possible to form this amplifier with a multiplier on a single chip.

### Thirteenth Embodiment

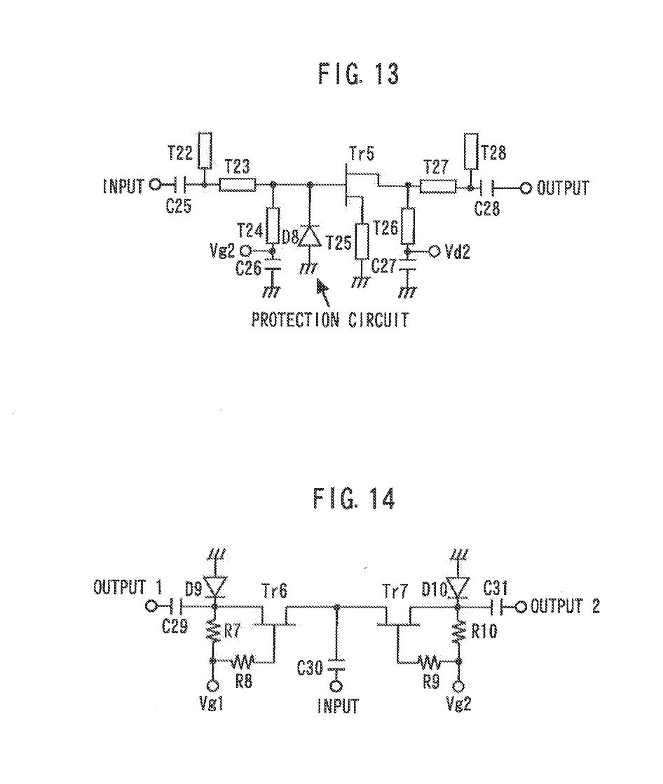

FIG. 13 is a diagram showing an amplifier with a protection circuit in accordance with a thirteenth embodiment of the present invention. This amplifier has capacitances C25 to C28, a diode D8, transmission lines T22 to T28, and a transistor Tr5. The diode D8 of the protection circuit may be configured as the vertical diode of any one of the first to eighth embodiments, and the transistor Tr5 of the amplifier may be configured as the lateral transistor of that embodiment, thereby making it possible to form this amplifier with a protection circuit on a single chip.

### Fourteenth Embodiment

FIG. 14 is a diagram showing a switch in accordance with a fourteenth embodiment of the present invention. This switch is a single pole double throw (SPDT) switch, and has capacitances C29 to C31, diodes D9 and D10, resistances R7 to R10, and transistors Tr6 and Tr7. The diodes D9 and D10 may be configured as the vertical diode of any one of the first to eighth embodiments, and the transistors Tr6 and Tr7 may be configured as the lateral transistor of that embodiment, thereby making it possible to form this switch on a single chip.

### Fifteenth Embodiment

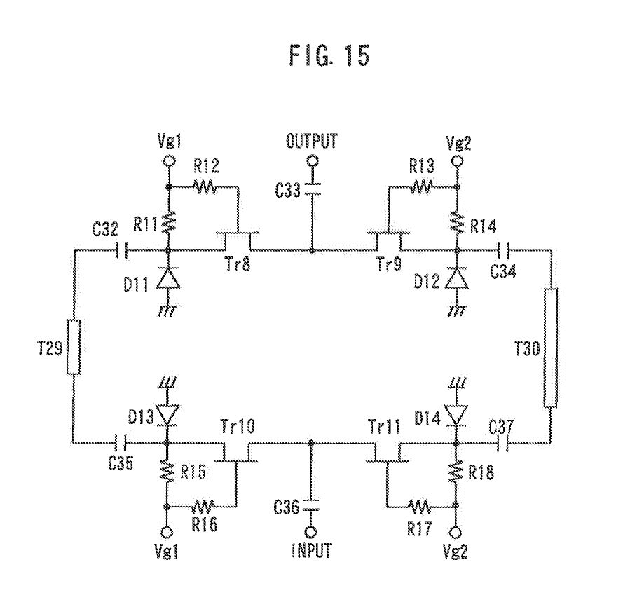

FIG. 15 is a diagram showing a phase shifter in accordance with a fifteenth embodiment of the present invention. This phase shifter is made up of two SPDT switches connected together, and has capacitances C32 to C37, diodes D11 to D14, resistances R11 to R18, transistors Tr8 to Tr11, a reference transmission line T29, and a phase shifting transmission line T30. The diodes D11 to D 14 may be configured as the vertical diode of any one of the first to eighth embodiments, and the transistors Tr8 to Tr11 may be configured as the lateral transistor of that embodiment, thereby making it possible to form this phase shifter on a single chip.

### Sixteenth Embodiment

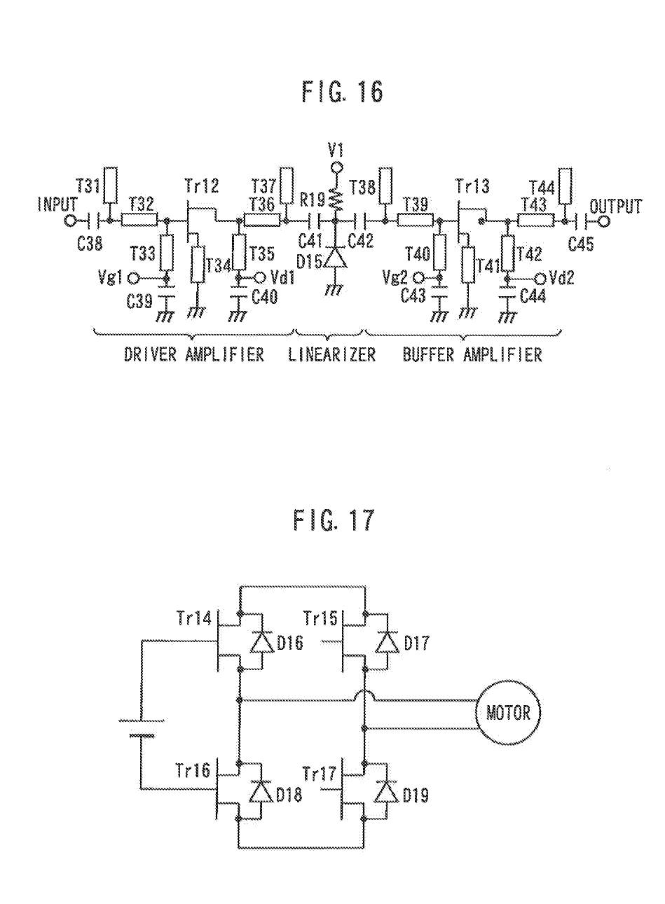

FIG. 16 is a diagram showing an amplifier with a linearizer in accordance with a sixteenth embodiment of the present invention. Capacitances C38 to C40, transmission lines T31 to T37, and a transistor Tr12 form the first stage buffer amplifier. Capacitances C41 and C42, a diode D15, and a resistance R19 form a linearizer. Capacitances C43 to C45, transmission lines T38 to T44, and a transistor Tr13 form the second stage buffer amplifier. The diode D15 of the linearizer may be configured as the vertical diode of any one of the first to eighth embodiments, and the transistors Tr12 and Tr13 of the amplifiers may be configured as the lateral transistor of that embodiment, thereby making it possible to form this amplifier with a linearizer on a single chip.

### Seventeenth Embodiment

FIG. 17 is a diagram showing an inverter in accordance with a seventeenth embodiment of the present invention. This inverter has diodes D16 to D19 and transistors Tr14 to Tr17. The diodes D16 to D19 may be configured as the vertical diode of any one of the first to eighth embodiments, and the transistors Tr14 to Tr17 may be configured as the lateral transistor of that embodiment, thereby making it possible to form this inverter on a single chip.

It should be noted that the vertical diodes and the lateral transistors of the first to eighth embodiments may be applied to communication devices, radar devices, power control devices, etc., in addition to the devices of the ninth to seventeenth embodiments described above. This enables each of these devices to be formed on a single chip.

Obviously many modifications and variations of the present invention are possible in the light of the above teachings. It is therefore to be understood that within the scope of the appended claims the invention may be practiced otherwise than as specifically described.

The entire disclosure of Japanese Patent Application No. 2012-236846, filed on Oct. 26, 2012, including specification, claims, drawings, and summary, on which the Convention priority of the present application is based, is incorporated herein by reference in its entirety.

1. A monolithic integrated circuit comprising:
a substrate having a diode region and a transistor region;
a first semiconductor layer on the substrate in the diode region and in the transistor region;
a second semiconductor layer on the first semiconductor layer in the diode region and in the transistor region;
a third semiconductor layer on the second semiconductor layer in the transistor region but not in the diode region;
a first electrode in the diode region and connected to the first semiconductor layer;
a second electrode in the diode region and connected to the second semiconductor layer; and
a source electrode, a gate electrode, and a drain electrode on the third semiconductor layer.

2. The monolithic integrated circuit according to claim 1, wherein the substrate includes a via hole in the diode region, and the first electrode is on a lower surface of the first semiconductor layer exposed in the via hole.

3. The monolithic integrated circuit according to claim 1, wherein the first electrode is on an upper surface of the first semiconductor layer in an area where the second semiconductor layer is not present in the diode region.

4. The monolithic integrated circuit according to claim 1, wherein the third semiconductor layer includes
an i-type electron traveling layer,
an electron supply layer on the electron traveling layer, and
the electron supply layer has a wider bandgap than the electron traveling layer.

5. The monolithic integrated circuit according to claim 4, further comprising a p-type semiconductor layer, located between the second semiconductor layer and the electron traveling layer, in the transistor region.

6. The monolithic integrated circuit according to claim 4, wherein the second semiconductor layer has a wider bandgap than the electron traveling layer.

7. The monolithic integrated circuit according to claim 1, wherein the first and second semiconductor layers are n-type, and the second semiconductor layer has a higher dopant impurity concentration than the first semiconductor layer.

8. The monolithic integrated circuit according to claim 1, wherein the first semiconductor layer is p-type and the second semiconductor layer is n-type.

9. The monolithic integrated circuit according to claim 1, further comprising an i-type semiconductor layer located between the first semiconductor layer and the second semiconductor layer, wherein one of the first and second semiconductor layers is p-type and the other of the first and second semiconductor layers is n-type

10. The monolithic integrated circuit according to claim 1, further comprising an etch stopper layer located between the second semiconductor layer and the third semiconductor layer.

11. The monolithic integrated circuit according to claim 1, further comprising an insulating layer insulating the first semiconductor layer in the diode region from the first semiconductor layer in the transistor region.

12. The monolithic integrated circuit according to claim 1, wherein the first semiconductor layer in the diode region is separated from the first semiconductor layer in the transistor region by a mesa.

13. The monolithic integrated circuit according to claim 1, wherein the monolithic integrated circuit is applied to any one of a receiver circuit with a mixer, a voltage-controlled oscillator with a varactor, an amplifier with a varactor, an amplifier with a multiplier, an amplifier with a protection circuit, a switch, a phase shifter, an amplifier with a linearizer, an inverter, a communication device, a radar device, and a power control device.
